(19) United States
(12) Patent Application Publication
(10) Pub. No.: US 2013/0118009 A1
(43) Pub. Date: May 16, 2013

(54) METHOD FOR MANUFACTURING PRINTED CIRCUIT BOARD

(71) Applicant: RUI-WU LIU, Shenzhen City (CN)

(72) Inventor: RUI-WU LIU, Shenzhen City (CN)

(21) Appl. No.: 13/658,780

(22) Filed: Oct. 23, 2012

(30) Foreign Application Priority Data
Nov. 15, 2011 (CN) 201110361345.6

(51) Int. Cl. H05K 3/30

(52) U.S. Cl. 29/841

(57) ABSTRACT

A method for manufacturing a printed circuit board includes the following steps. First, a first copper foil having first and second surfaces is provided. Second, the first copper foil is etched to remove portions of the first copper foil to convert the first copper foil into an intermediate structure having a substrate and first protrusions. Each first protrusion is exposed at the first surface. Third, a first insulation material fills into gaps between the first protrusions. Fourth, a second copper foil is laminated on the first surface. Fifth, the intermediate structure is etched from the second surface to remove portions of substrate to convert the substrate into second protrusions. Sixth, a second insulation material is infilled into gaps between the second protrusions. Seventh, a third copper foil is laminated on the second surface. Finally, the copper foils are patterned to be second and third patterns.

### BACKGROUND

1. Technical Field

The present disclosure generally relates to printed circuit boards, and particularly to a printed circuit board having a longer storage time and a method for manufacturing the printed circuit board.

2. Description of Related Art

Printed circuit boards (PCBs) are widely used in electronic devices. PCBs include double-sided printed circuit boards and multilayer printed circuit boards. Plated through holes may be used to electrically connect an electrical pattern to another electrical pattern. Plated through holes are made by punching, melanism or electro-less plating, electroplating, or other processes. A punching device and an electroplating device are expensive, the cost of the PCBs manufactured by the punching device and the electroplating device is thus high. Further, it is hard to control the precision of punching and electroplating, and the rate of finished products of the PCBs is thus lower.

What is needed, therefore, is a printed circuit board and a method for manufacturing the printed circuit board to overcome the above-described problems.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIGS. 1-13 show successive stages in the making of a printed circuit board according to an exemplary embodiment.

### DETAILED DESCRIPTION

A method for manufacturing a printed circuit board and a printed circuit board according to embodiments will be described with reference to the drawings.

The method for manufacturing a printed circuit boards includes the following steps.

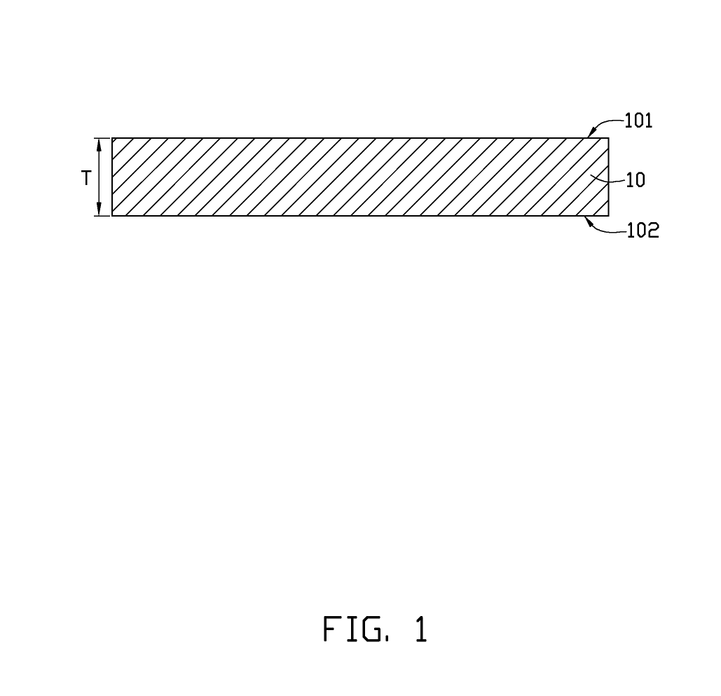

In step 1, referring to FIG. 1, a first copper foil 10 is provided. The first copper foil 10 includes a first surface 101 and an opposite second surface 102. The first copper foil 10 can be a rolled copper foil, and the thickness T of the first copper foil 10 is in a range from 12 micrometers to 120 micrometers.

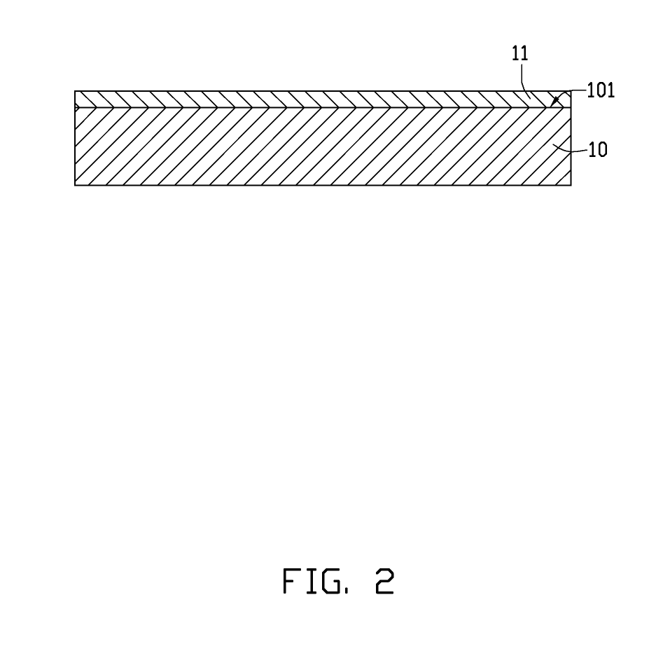

In step 2, referring to FIG. 2 to FIG. 5, an etching process is applied to the first surface 101 of the first copper foil 10 to remove portions of the first copper foil 10 near the first surface 101, thereby converting the first copper foil 10 into an intermediate structure 12. The intermediate structure 12 includes a substrate 120 near the second surface 102 and a plurality of first protrusions 121 extending towards the first surface 101 from the substrate 120. The substrate 120 consists of a part of the first copper foil 10 near the second surface 102.

The first protrusions 121 consist of the unetched portions of the first copper foil 10 near the first surface 101, and each first protrusion 121 is exposed at the first surface 101. The sum of the thickness T₁ of the substrate 120 and the thickness T₂ of the first protrusion 12 (i.e. the height of the first protrusion 12) is equal to the original thickness T of the first copper foil 10. Normally, the thickness T₁ of the substrate 120 is in a range from forty percent of the thickness T of the first copper foil 10 to sixty percent of the thickness T of the first copper foil 10. Each first protrusion 121 is substantially cylindrical, and the diameter of each first protrusion 12 is in a range from 50 micrometers to 200 micrometers.

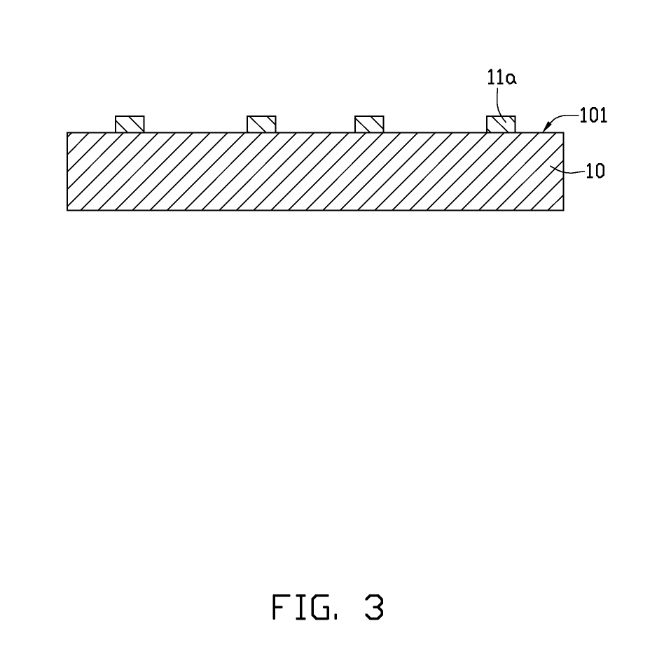

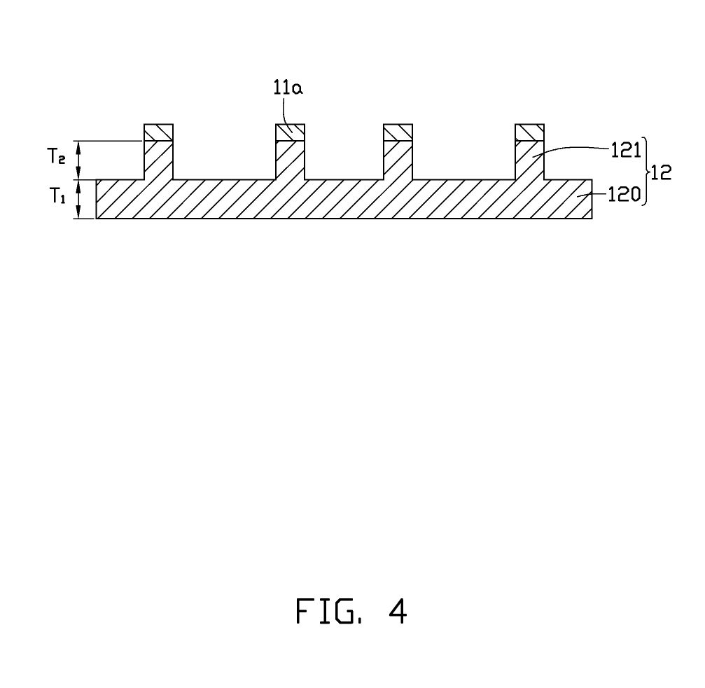

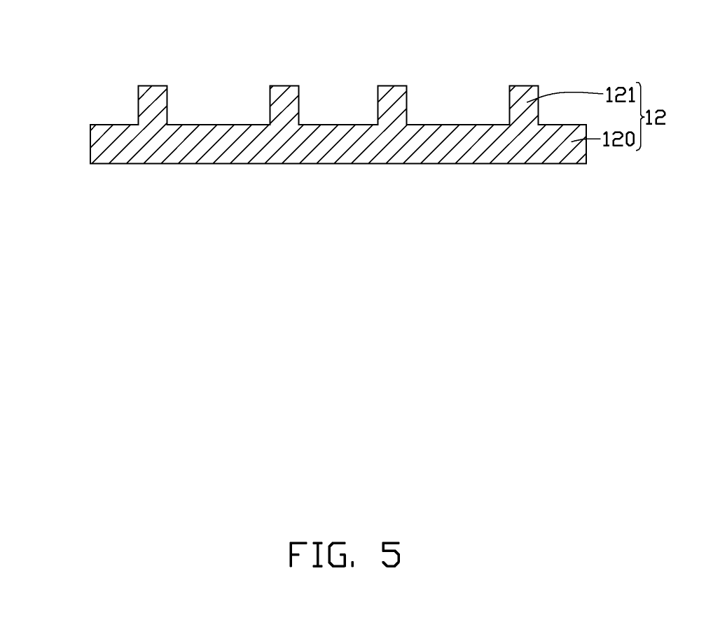

The first copper foil 10 is manufactured to the intermediate structure 12 by an image transmission process and an etching technology. In detail, the first copper foil 10 can be manufactured to the intermediate structure 12 by the following steps. First, referring to FIG. 2, a photo-resist layer 11 is formed on the first surface 101 by coating. Second, referring to FIG. 3, the photo-resist layer 11 is patterned by exposing and developing to form a patterned photo-resist layer 11a. The patterned photo-resist layer 11a is configured for creating the first protrusions 121 In detail, the patterned photo-resist layer 11a covers a part of the first surface 101 corresponding to the first protrusions 121 which will be formed, and exposes the other part of the first surface 101 surrounding the first protrusions 121. Third, referring to FIG. 4, the exposed parts of the first copper foil 10 are etched by a chemical solution or a laser until the depth of etching is in a range from forty percent of the thickness T of the first copper foil 10 to sixty percent of the thickness T of the first copper foil 10, thereby forming the first protrusions 121. Finally, referring also to FIG. 5, the patterned photo-resist layer 11a is removed from the first protrusions 121, thereby obtaining the intermediate structure 12.

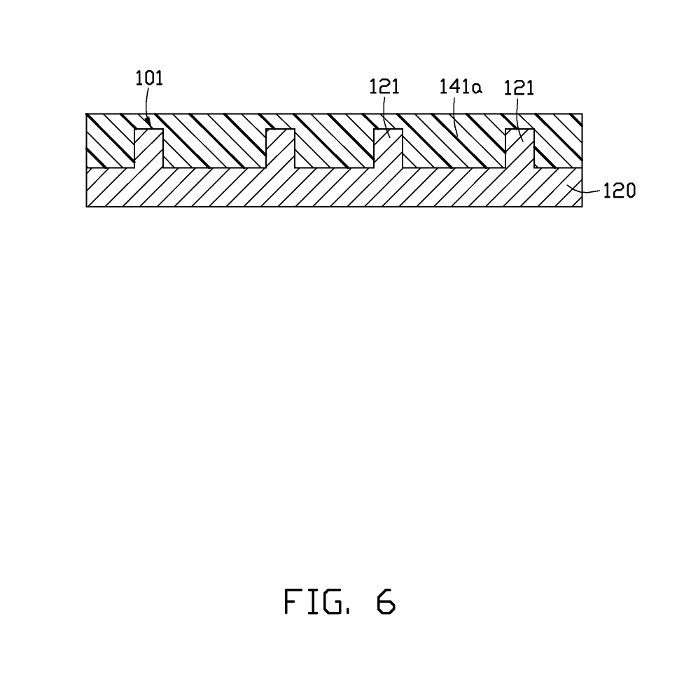

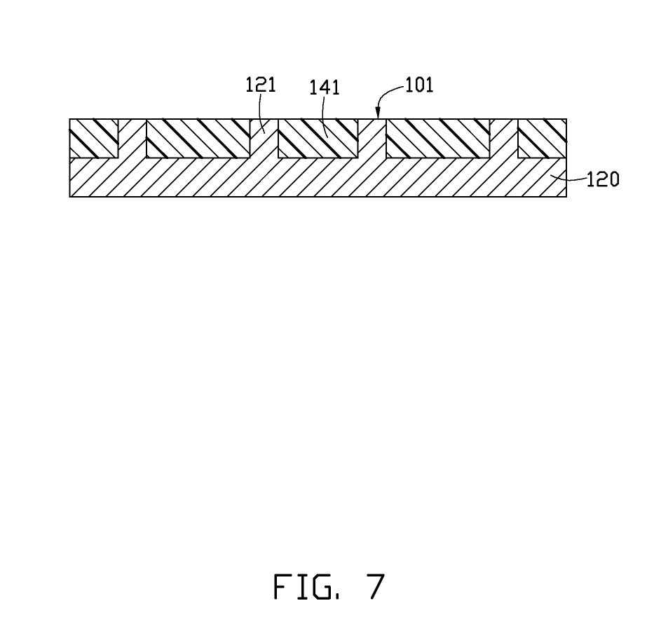

In step 3, referring to FIGS. 6 and 7, a first insulation material 141 is infilled into gaps between the first protrusions 121 until the first insulation material 141 is in contact with the substrate 120 and sufficiently fills the gaps between the first protrusions 12. In addition, the surface of the first insulation material 141 furthest from the substrate 120 is coplanar with the top surfaces of the first protrusions 121. In other words, the overall finished surface is as flat as that of the first surface 101.

The first insulation material 141 can be hard epoxy resin, Polyimide(PI), Polyethylene Terephthalate(PET), Polyethylene naphthalate(PEN), or the like, and may be formed either by a lamination method, where prepreg is preferred, or by a printing method using any of the above material.

By laminating a prepreg or printing liquid resin on the first surface 101, the prepreg or the liquid resin becomes the first insulation material 141, and is infilled into the gaps between the first protrusions 121.

The lamination method for infilling the first insulation material 141 between the first protrusions 121 can include the following steps: first, a prepreg is positioned on the first surface 101, the shape of the prepreg is the same as the shape of the first copper foil 10, and the thickness of the prepreg is similar to the thickness T₂ of the first protrusions 121; second, the prepreg is laminated on the first surface 101 by a lamination machine (not shown), and the prepreg is heated to melting point and will then fill the gaps between the first protrusions 121 in the process of lamination; finally, the melted prepreg is solidified to be the first insulation material 141.

To fill the gaps between the first protrusions 121 by the printing method, liquid resin is printed on the first surface 101 and becomes the first insulation material 141. In detail, the printing method includes the following steps: first, a screen is positioned on the first protrusions 121, the screen including a printing pattern for covering the first protrusions 121 and exposing the substrate 120; second, liquid resin passes through the printing pattern to coat the exposed substrate 120 by using a scraper; finally, the liquid resin is solidified to obtain the first insulation material 141 between all of the first protrusions 121.

In the present embodiment, the first insulation material 141 fills the gaps between the first protrusions 121. In detail, referring to FIG. 6, in order to fully fill the gaps between the first protrusions 121, the thickness of the prepreg 141a is greater than the thickness T₂ of the first protrusion 121. In other words, after laminating and solidifying, the solidified prepreg 141 a may cover the first protrusions 121 so they are submerged. In such case, referring also to FIG. 7, a scratch brush process is needed to remove the solidified prepreg 141a until the surface of the solidified prepreg 141a furthest from the substrate 120 is coplanar with the top surfaces of the first protrusions 121 furthest from the substrate 120. In other words, after scratch brushing, the scratch brushed prepreg 141a becomes the first insulation material 141, and this scratch brushing process may also be required after the printing method to make the surface of the solidified resin furthest from the substrate 120 is coplanar with the top surfaces of the first protrusions 121 furthest from the substrate 120.

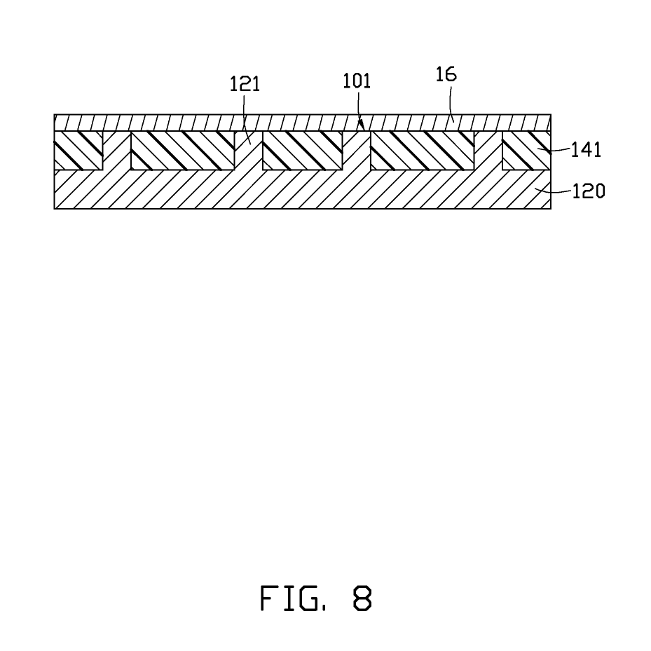

In step 4, referring to FIG. 8, a second copper foil 16 is laminated on the first surface 101. In other words, the second copper foil 16 is laminated on the end surfaces of the first protrusions 121 furthest from the substrate 120 and the surface of the first insulation material 141 furthest from the substrate 120. Because the first protrusions 121 are exposed at the first surface 101, the second copper foil 16 is electrically connected to the first protrusions 121. The thickness of the second copper foil 16 is less than the thickness of the first copper foil 10, and this dimension is also smaller than the diameter of the first protrusion 121. In the present embodiment, the thickness of the second copper foil 16 is in a range from 12 micrometers to 18 micrometers.

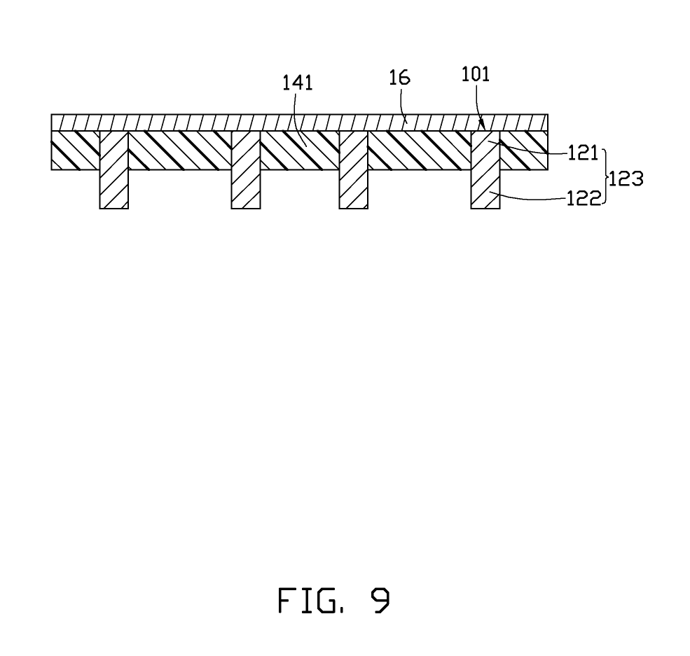

In step 5, referring to FIG. 9, the intermediate structure 12 is etched from the second surface 102 to remove portions of the substrate 120, thereby converting the substrate into a plurality of second protrusions 122. The second protrusions 122 is aligned with and electrically connected to the respective first protrusions 121. The first protrusions 121 and the second protrusions 122 cooperatively form a plurality of copper pillars 123. Each of the copper pillars 123 is substantially cylindrical. One end of each copper pillar 123 is exposed at the first surface 101, and is in contact with the second copper foil 16. The other end of each copper pillar 123 is exposed at the second surface 102. The diameter of each copper pillar 123 is equal to the diameter of each first protrusion 121, and is also equal to the diameter of each second protrusion 122. That is, the diameter of each copper pillar 123 is in a range from 50 micrometers to 200 micrometers.

It is understood that the second protrusions 122 can also be formed by an image transmission process and an etching technology. In other words, the method for forming the second protrusions 122 can be same as the method for forming the first protrusions 121.

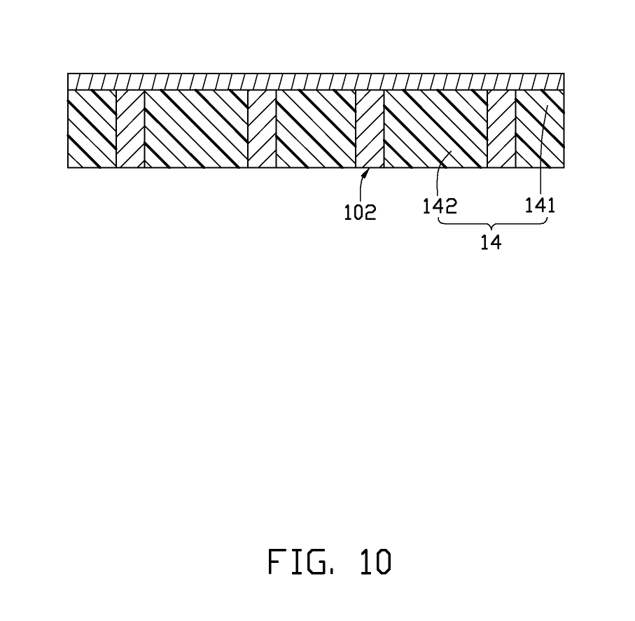

In step 6, referring to FIG. 10, a second insulation material 142 is infilled into the gaps between the second protrusions 122 to make the second insulation material 142 fully fill the gaps between the second protrusions 122. The surface of the second insulation material 142 furthest from the second copper foil 16 is coplanar with the end surfaces of the second protrusions 122 furthest from the second copper foil 16. It is understood that the method for forming the second insulation material 142 in step 6 can be similar to the method for forming the first insulation material 141 in step 3. In other words, laminating a prepreg or printing liquid resin on the second surface 102 results in the second insulation material 142 being infilled into the gaps between the second protrusions 122.

If the solidified prepreg or solidified liquid resin covers the second protrusions 122 after depositing the melted prepreg and liquid resin into the gaps between the second protrusions 122, a scratch brush process is needed again to remove solidified prepreg or solidified liquid resin until the surface of the solidified prepreg or solidified liquid resin furthest from the second copper foil 16 is coplanar with the end surfaces of the second protrusions 122 furthest from the second copper foil 16. In other words, after scratch brushing, the scratch brushed prepreg or liquid resin becomes the second insulation material 142.

In the present embodiment, it is preferred that the first insulation material 141 and the second insulation material 142 are the same material, for example, hard epoxy resin, PI, PET, PEN, or the like.

The first insulation material 141 and the second insulation material 142 adhere to each other to form an insulation layer 14. The copper pillars 123 are dispersed in the insulation layer 14. The thickness of the insulation layer 14 is equal to the length of each copper pillar 123. The upper surface of the insulation layer 14 near the second copper foil 16 is coplanar with the upper end surfaces of the copper pillars 123 near the second copper foil 16, and cooperatively defines a surface equivalent to the first surface 101. The bottom surface of the insulation layer 14 furthest from the second copper foil 16 is coplanar with the bottom end surfaces of the copper pillars 123 furthest from the second copper foil 16, and cooperatively defines a surface equivalent to the second surface 102.

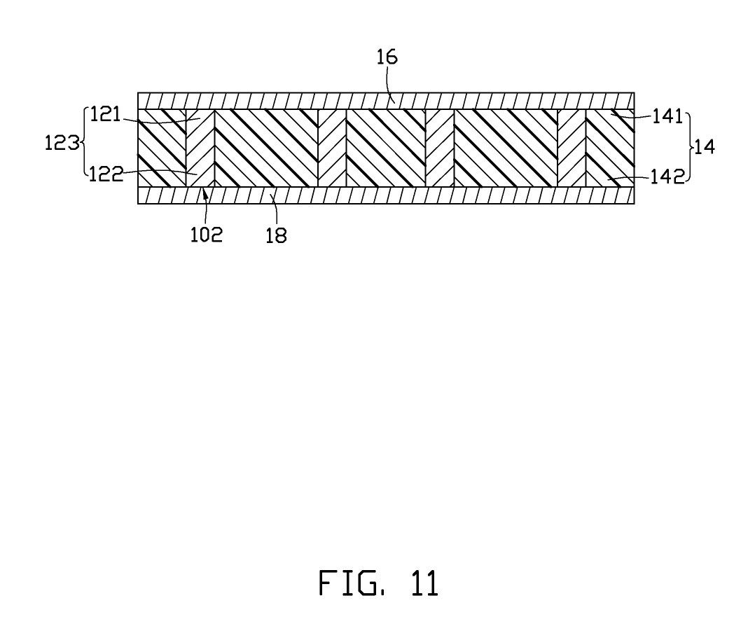

In step 7, referring to FIG. 11, a third copper foil 18 is laminated on the second surface 102. In other words, the third copper foil 18 is laminated on the bottom surface of the insulation layer 14 furthest from the second copper foil 16 and the bottom end surfaces of the copper pillars 123 furthest from the second copper foil 16. Thus, each of second protrusions 122 is in contact with the third copper foil 18. The thickness of the third copper foil 18 is less than the thickness of the first copper foil 10, and this dimension is also smaller than the diameter of the copper pillar 123. The thickness of the third copper foil 18 can also be similar to the thickness of the second copper foil 16. In the present embodiment, the thickness of the third copper foil 18 is in a range from 12 micrometers to 18 micrometers.

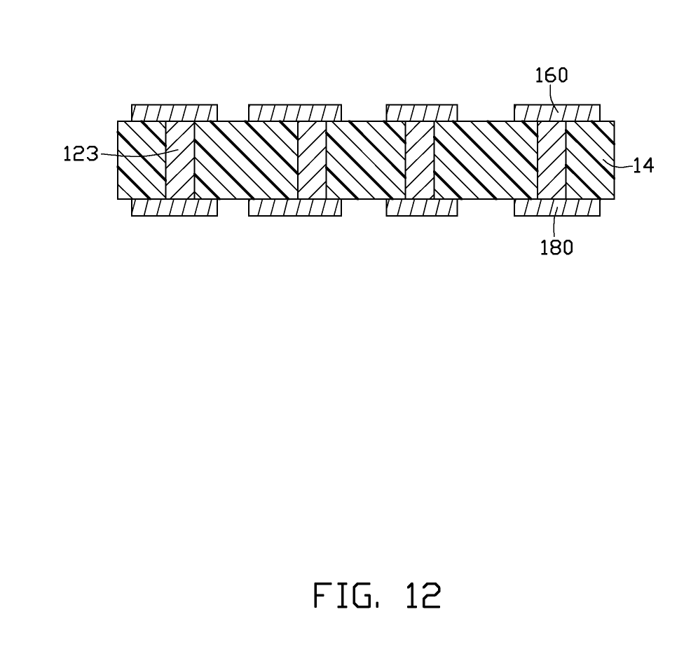

In step 8, referring to FIG. 12, the second copper foil 16 is patterned to convert the second copper foil 16 into a second conductive pattern 160, and the third copper foil 18 is patterned to convert the third copper foil 18 into a third conductive pattern 180. The second conductive pattern 160 is electrically connected to the third conductive pattern 180 via the copper pillars 123.

The second copper foil 16 can be patterned to form a second conductive pattern 160 by an image transmission process and an etching technology. The third copper foil 18 can also be patterned to form a third conductive pattern 180 by an image transmission process and an etching technology.

Each of the second conductive pattern 160 and the third conductive pattern 180 includes a plurality of electrically conductive wires, a plurality of connection points, and a plurality of connection terminals. Each of the copper pillars 123 can be electrically connected to an electrically conductive wire of the second conductive pattern 160 and an electrically conductive wire of the third conductive pattern 180.

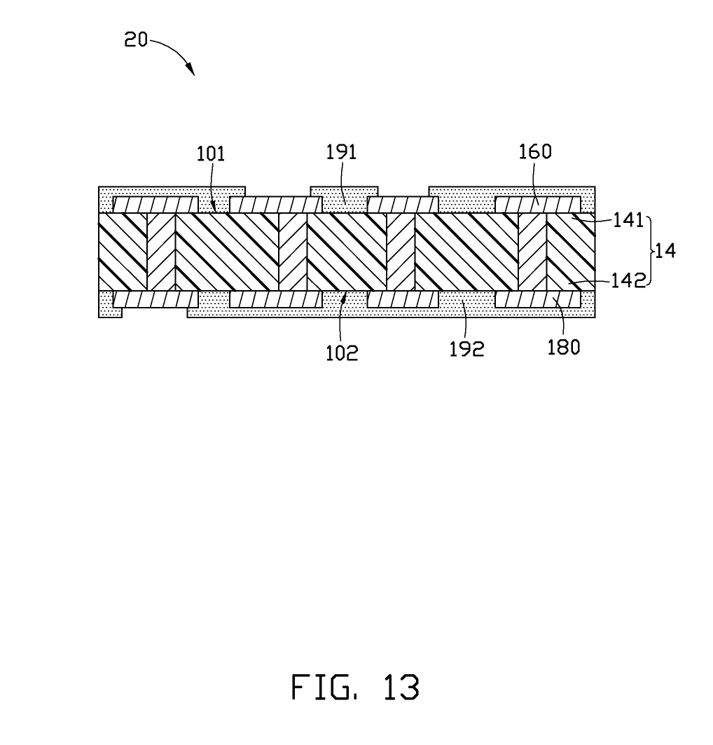

In step 9, referring to FIG. 13, after forming the second conductive pattern 160 and the third conductive pattern 180, a first protection layer 191 is formed on the second conductive pattern 160, and a second protection layer 182 is formed on the third conductive pattern 180. Thus, a printed circuit board 20 is obtained.

The first protection layer 191 covers the second conductive pattern 160 and the surface of the first insulation material 141 exposed from the second conductive pattern 160, and protects the second conductive pattern 160 from damage. The second protection layer r192 covers the third conductive pattern 180 and the surface of the second insulation material 142 exposed from the third conductive pattern 180, and protects the third conductive pattern 180 from damage.

When the first insulation material 141 and the second insulation material 142 are hard resins, the first protection layer 191 and the second protection layer 192 usually are solder masks. When the first insulation material 141 and the second insulation material 142 are flexible resins, the first protection layer 191 and the second protection layer 192 usually are coverlayers.

In other embodiments, after forming the first protection layer 191 and the second protection layer 192, electronic devices can be arranged on the printed circuit board 20. The lack of through holes in the printed circuit board 20 allows more efficient placement of, and a greater number of, components in the electronic devices. In addition, because through plating holes are replaced with the copper pillars 123, the purchasing cost of the punching device and electroplating device is avoided, and the risks of the punching process and electroplating process can be avoided.

While certain embodiments have been described and exemplified above, various other embodiments will be apparent from the foregoing disclosure to those skilled in the art. The disclosure is not limited to the particular embodiments described and exemplified but is capable of considerable variation and modification without departure from the scope and spirit of the appended claims.

What is claimed is:

1. A method for manufacturing a printed circuit board, comprising:
providing a first copper foil, the first copper foil including a first surface and an opposite second surface;
etching the first surface of the first copper foil to remove portions of the first copper foil, thereby converting the first copper foil into an intermediate structure, the intermediate structure comprising a substrate and a plurality of first protrusions, each of the first protrusions being exposed at the first surface;
filling a first insulation material into gaps between the first protrusions, and making the first insulation material coplanar with the first surface;
laminating a second copper foil on the first surface;
etching the intermediate structure from the second surface to remove portions of the substrate, thereby converting the substrate into a plurality of second protrusions, the second protrusions aligned with and connected to the respective first protrusions, the first and second protrusions, cooperatively forming a plurality of copper pillars, each of copper pillars being exposed at the second surface;
filling a second insulation material into gaps between the second protrusions, and making the second insulation material coplanar with the second surface;
laminating a third copper foil on the second surface; and
patterning the second copper foil to convert the second copper foil into a second conductive pattern, and patterning the third copper foil to convert the third copper foil into a third conductive pattern, the second conductive pattern being electrically connected to the third conductive pattern via the copper pillars.

2. The method of claim 1, wherein the first insulation material is the same as the second insulation material.

3. The method of claim 1, wherein the first insulation material is infilled into the gaps between the first protrusions by laminating a prepreg or printing liquid resin on the first surface.

4. The method of claim 3, wherein after filling the first insulation material in gaps between the first protrusions, a part of the first insulation material protruding the first surface is removed to make the first insulation material coplanar with the first surface.

5. The method of claim 1, wherein the second insulation material is infilled into the gaps between the second protrusions by laminating a prepreg or printing liquid resin on the first surface.

6. The method of claim 5, wherein after filling the second insulation material in gaps between the second protrusions, a part of the second insulation material protruding the second surface is removed to make the second insulation material coplanar with the second surface.

7. The method of claim 1, wherein the thickness of the first copper foil is greater than the thickness of the second copper foil, and is also greater than the thickness of the third copper foil, the diameter of the copper pillar is greater than the thickness of the second copper foil, and is also greater than the thickness of the third copper foil.

8. The method of claim 1, wherein the sum of the thickness of the substrate and the height of the first protrusion is equal to the thickness of the first copper foil, the height of the second protrusion is equal to the thickness of the substrate.

9. The method of claim 1, wherein after patterning the second copper foil, and patterning the third copper foil, the method further comprises a step of forming a first protection layer on the second conductive pattern, and forming a second protection layer on the third conductive pattern.

10. A method for manufacturing printed circuit board, comprising:
providing a first copper foil, the first copper foil including a first surface and an opposite second surface;
etching the first surface of the first copper foil to remove portions of the first copper foil, thereby converting the first copper foil into an intermediate structure, the intermediate structure comprising a substrate and a plurality of first protrusions, each of the first protrusions being exposed at the first surface;
filling a first insulation material into gaps between the first protrusions, and making the first insulation material between the first protrusions coplanar with the first surface;
laminating a second copper foil on the first surface;
etching the second surface of the intermediate structure to remove portions substrate, thereby converting the substrate into a plurality of second protrusions, the second protrusions spatially corresponding to the first protrusions, and each of the second protrusions being connected to the corresponding first protrusion, thereby forming a plurality of copper pillars, each of the copper pillars being exposed at the second surface;
filling a second insulation material into gaps between the second protrusions, and making the second insulation material between the second protrusions coplanar with the second surface;
laminating a third copper foil on the second surface;
patterning the second copper foil to convert the second copper foil into a second conductive pattern, and patterning the third copper foil to convert the third copper foil into a third conductive pattern, the second conductive pattern being electrically connected to the third conductive pattern via the copper pillars; and
forming a first protection layer on the second conductive pattern, and forming a second protection layer on the third conductive pattern.

11. The method of claim 10, wherein the first insulation material between the first protrusions is the same as the second insulation material between the second protrusions.

12. The method of claim 10, wherein the first insulation material is infilled into the gaps between the first protrusions by laminating a prepreg or printing liquid resin on the first surface.

13. The method of claim 12, wherein after filling the first insulation material into gaps between the first protrusions, a part of the first insulation material protruding the first surface is removed to make the first insulation material coplanar with the first surface.

14. The method of claim 10, wherein the second insulation material is infilled into the gaps between the second protrusions by laminating a prepreg or printing liquid resin on the first surface.

15. The method of claim 14, wherein after filling the second insulation material into the gaps between the second protrusions, a part of the second insulation material protruding the second surface is removed to make the second insulation material coplanar with the second surface.

16. The method of claim 10, wherein the thickness of the first copper foil is greater than the thickness of the second copper foil, and is also greater than the thickness of the third copper foil, the diameter of the copper pillar is greater than the thickness of the second copper foil, and is also greater than the thickness of the third copper foil.

17. The method of claim 10, wherein the sum of the thickness of the substrate and the height of the first protrusion is equal to the thickness of the first copper foil, the height of the second protrusion is equal to the thickness of the substrate.
